(19) United States
(12) Patent Application Publication
(10) Pub. No.: US 2012/0051003 A1
(43) Pub. Date: Mar. 1, 2012

(54) PRINTED CIRCUIT BOARD

(75) Inventor: HUNG-YI CHIEN, Tu-Cheng (TW)

(73) Assignee: HON HAI PRECISION INDUSTRY CO., LTD., Tu-Cheng (TW)

(21) Appl. No.: 12/953,496

(22) Filed: Nov. 24, 2010

(30) Foreign Application Priority Data
Aug. 25, 2010 (TW) 99128479

(51) Int. Cl. H05K 7/00

(52) U.S. Cl. 361/748

(57) ABSTRACT

A printed circuit board (PCB) includes an electronic element, a signal line, an input/output (I/O) interface, and a varistor. The I/O interface is connected to the electronic element through the signal line. The varistor includes a first terminal connected to the I/O interface, and a grounded second terminal. The varistor is close to the I/O interface, to eliminate static electricity flowing into the PCB from the I/O interface.

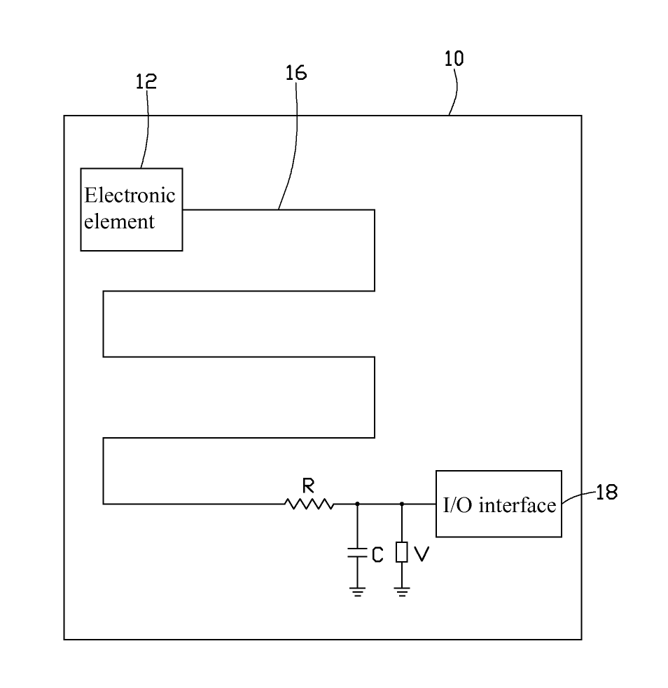

### BACKGROUND

1. Technical Field

The present disclosure relates to a printed circuit board (PCB).

2. Description of Related Art

Generally, a number of input/output (I/O) interfaces, such as universal serial bus interfaces, and video graphics array interfaces, are assembled on a PCB of an electronic device, to connect peripheral equipment. Because I/O interfaces are exposed out of a chassis of the electronic device, when people and devices carrying static electricity contact the I/O interfaces, the static electricity flows into the PCB through the I/O interfaces, which can damage electronic elements mounted on the PCB. Additionally, noise of the PCB will be transmitted out through the I/O interfaces and peripheral equipments connected to the I/O interfaces, to cause electromagnetic interference.

### BRIEF DESCRIPTION OF THE DRAWING

Many aspects of the present embodiments can be better understood with reference to the following drawing. The components in the drawing are not necessarily drawn to scale, the emphasis instead being placed upon clearly illustrating the principles of the present embodiments. Moreover, in the drawing, all the views are schematic, and like reference numerals designate corresponding parts throughout the several views.

The drawing is a schematic diagram of a printed circuit board (PCB) in accordance with an embodiment.

### DETAILED DESCRIPTION

The disclosure, including the accompanying drawing, is illustrated by way of example and not by way of limitation. It should be noted that references to “an” or “one” embodiment in this disclosure are not necessarily to the same embodiment, and such references mean at least one.

Referring to the drawing, an embodiment of a printed circuit board (PCB) 10 includes an electronic element 12, a signal line 16, an input/output (I/O) interface 18, a resistor R, a capacitor C, and a varistor V. The electronic element 12 is connected to the I/O interface 18 through the signal line 16. The resistor R includes a first terminal connected to the electronic element 12 through the signal line 16, and a second terminal connected to the I/O interface 18. The capacitor C includes a first terminal connected to the second terminal of the resistor R, and a grounded second terminal. The varistor V includes a first terminal connected to the first terminal of the capacitor C, and a grounded second terminal. It may be understood that the varistor V stays non-conductive when voltage of the varistor V is well below a breakdown voltage of the varistor V. Otherwise, the varistor V becomes conductive.

The resistor R, the capacitor C, and the varistor V are closed to the I/O interface 18, the varistor V is closest to the I/O interface 18, the capacitor C is between the resistor R and the varistor V. In one embodiment, the electronic element 12 is a chip, such as a south bridge. The I/O interface 18 may be a serial bus interface, or a video graphics array interface. The PCB 10 is assembled in a chassis of an electronic device (not shown), the I/O interface 18 is exposed out of the chassis to connect a peripheral equipment (not shown).

When people and devices carrying static electricity contact the I/O interface 18, the static electricity flows into the PCB 10 through the I/O interface 18, and enters the varistor V, which is closest to the I/O interface 18. A transient surge voltage generated by the static electricity is greater than the breakdown voltage of the varistor V, the varistor V becomes conductive. Parts of the static electricity is absorbed by the varistor V, and most parts of the static electricity flows into ground through the varistor V, to protect the electronic element 12 from being damaged by the static electricity.

When the static electricity is not eliminated completely by the varistor V, the resistor R will prevent the remaining static electricity from flowing into the electronic element 12. Therefore, the resistor R can further protect the electronic element 12.

When a signal with noise is transmitted on the signal line 16, the noise will be filtered by the capacitor C. Therefore, the noise cannot be transmitted out through the I/O interface 18 and the peripheral equipment connected to the I/O interface 18 to cause electromagnetic interference.

In one embodiment, because hazard of the static electricity to the PCB 10 is worse than the electromagnetic interference, the varistor V is assembled closest to the I/O interface 18, to eliminate the static electricity. Additionally, because the noise transmitted out by the I/O interface 18 may exist anywhere along the signal line 16, the capacitor C is assembled closer to the I/O interface 18, to filter the noise better. Moreover, the resistor R is used to further protect the electronic element 12 from being damaged by the static electricity, therefore, the resistor R is assembled farther from the I/O interface 18 than the capacitor C.

As detailed above, according to assembling the resistor R, the capacitor C, and the varistor V close to the I/O interface 18, to eliminate the static electricity and filter the noise, the PCB 10 protects the electronic element 12 from being damaged by the static electricity, and prevents the noise from being transmitted out through the I/O interface 18 to cause electromagnetic interference.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A printed circuit board (PCB) comprising:
an electronic element;
a signal line;
an input/output (I/O) interface connected to the electronic element through the signal line; and
a varistor comprising a first terminal connected to the I/O interface, and a grounded second terminal;
wherein the varistor is close to the I/O interface, to eliminate static electricity flowing into the PCB from the I/O interface.

2. The PCB of claim 1, further comprising a capacitor comprising a first terminal connected to the first terminal of the varistor, and a grounded second terminal, wherein the capacitor is close the I/O interface but farther from the I/O interface than the varistor, to filter noise transmitted on the signal line.

3. The PCB of claim 2, further comprising a resistor comprising a first terminal connected to the electronic element through the signal line, and a second terminal connected to the first terminal of the capacitor, wherein the resistor is close to the I/O interface but farther from the I/O interface than the capacitor, and wherein the resistor prevents remaining static electricity that is not eliminated completely by the varistor from flowing into the electronic element.

4. A printed circuit board (PCB) comprising:
an electronic element;
a signal line;
an input/output (I/O) interface connected to the electronic element through the signal line;
a varistor comprising a first terminal connected to the I/O interface, and a grounded second terminal;
a capacitor comprising a first terminal connected to the first terminal of the varistor, and a grounded second terminal; and
a resistor comprising a first terminal connected to the electronic element through the signal line, and a second terminal connected to the first terminal of the capacitor;
wherein the resistor, the capacitor, and the varistor are close to the I/O interface, the varistor is closest to the I/O interface, the capacitor is between the resistor and the varistor; and
wherein the varistor eliminates static electricity flowing into the PCB from the I/O interface, the capacitor filters noise transmitted on the signal line, and the resistor prevents remaining static electricity that is not eliminated completely by the varistor from flowing into the electronic element.
